(19) United States
(12) Patent Application Publication
(10) Pub. No.: US 2025/0241151 A1
(43) Pub. Date: Jul. 24, 2025

(54) PIXEL CIRCUIT AND DISPLAY DEVICE INCLUDING SAME

(71) Applicant: LG Display Co., Ltd., Seoul (KR)

(72) Inventors: Jeong Hyeon CHOI, Paju-si (KR); Young Jun CHOI, Paju-si (KR); Min Kyu CHUN, Paju-si (KR)

(73) Assignee: LG Display Co., Ltd., Seoul (KR)

(21) Appl. No.: 18/962,601

(22) Filed: Nov. 27, 2024

(30) Foreign Application Priority Data
Jan. 18, 2024 (KR) 10-2024-0007772

(51) Int. Cl. H10K 59/131; H10K 59/121; H10K 59/80

(52) U.S. Cl. CPC H10K 59/131; H10K 59/1216; H10K 59/87

(57) ABSTRACT

A pixel circuit according to an embodiment and a display device including the same are discussed. The pixel circuit in one example includes a first light-emitting element, a second light-emitting element, a driving element configured to drive the first and second light-emitting elements, a first connection line connected between a source node of the driving element and a first anode electrode of the first light-emitting element, a second connection line connected between the source node of the driving element and a second anode electrode of the second light-emitting element, a first repair capacitor connected in parallel to the first connection line, and a second repair capacitor connected in parallel to the second connection line.

### CROSS-REFERENCE TO RELATED APPLICATION

This application claims priority to Korean Patent Application No. 10-2024-0007772, filed in the Republic of Korea on Jan. 18, 2024, the entire contents of which is hereby expressly incorporated by reference into the present application.

### BACKGROUND

### Field

The present disclosure relates to a pixel circuit and a display device including the same.

### Discussion of the Related Art

Display devices include a liquid crystal display (LCD) device, an electroluminescence display device, a field emission display (FED) device, a plasma display panel (PDP), and the like.

Electroluminescent display devices are divided into inorganic light emitting display devices and organic light emitting display devices according to a material of a light emitting layer. An active-matrix type organic light emitting display device includes an organic light emitting diode (hereinafter referred to as an “OLED”) which emits light by itself, and has advantages, e.g., a response speed is fast and luminous efficiency, luminance, and a viewing angle are large.

Some of the display devices, for example, a liquid crystal display device or an organic light emitting display device includes a display panel including a plurality of sub-pixels, a driver for outputting a driving signal for driving the display panel, a power supply for generating power to be supplied to the display panel or the driver, and the like.

In such a display device, when a driving signal such as a scan signal, an EM signal, and a data signal is supplied to a plurality of pixels formed in the display panel, the selected pixel transmits light or emits light directly to thereby display an image.

### SUMMARY OF THE DISCLOSURE

In a display device, due to foreign substances during the process of manufacturing a pixel circuit of the display device, a defect in which one or more pixels do not operate properly, such as a dark point defect, can occur due to a short circuit between layers, particularly between the anode and cathode electrodes of a light-emitting element, which can increase poor quality issues.

The present disclosure is directed to solving all the above-described issues and other limitations associated with the related art.

The present disclosure provides a pixel circuit and a display device including the same.

It should be noted that objects of the present disclosure are not limited to the above-described objects, and other objects of the present disclosure will be apparent to those skilled in the art from the following descriptions.

A pixel circuit according to embodiments of the present disclosure can include a first light-emitting element; a second light-emitting element; a driving element configured to drive the first and second light-emitting elements; a first connection line connected between a source node of the driving element and a first anode electrode of the first light-emitting element; a second connection line connected between the source node of the driving element and a second anode electrode of the second light-emitting element; a first repair capacitor connected in parallel to the first connection line; and a second repair capacitor connected in parallel to the second connection line.

A display device according to embodiments of the present disclosure can include a substrate; a repair wire disposed on the substrate; a buffer layer covering the substrate on which the repair wire is formed; a first passivation layer disposed on the buffer layer and exposing a portion of the buffer layer; a clad layer disposed on the first passivation layer; a second passivation layer disposed on the clad layer and exposing a portion of the clad layer; an overcoat layer disposed on the second passivation layer and exposing a portion of the clad layer; a first anode electrode disposed on one side of the overcoat layer and electrically connected to one side of the clad layer through the overcoat layer and the second passivation layer; and a second anode electrode disposed on the other side of the overcoat layer and electrically connected to the other side of the clad layer through the overcoat layer and the second passivation layer.

According to one or more aspects of the present disclosure, a repair wire is added to the lower part of the clad layer that applies voltage to the anode electrode of the light-emitting element, and even if the clad layer without foreign substances is cut, voltage is applied to the anode of the light-emitting element through repair wire, thereby a successful repair process can be performed even if a foreign substance defect that cannot be confirmed by the human eye occurs.

The present disclosure can improve the overall production yield because normal driving of pixels is possible through the performance of the secondary repair process even if the primary repair process fails.

According to one or more aspects of the present disclosure, by additionally configuring a gate layer between the repair wire and the clad layer, it is possible to block the effect of laser light on the repair wire when the clad layer is cut.

According to one or more aspects of the present disclosure, low power driving and process optimization can be possible.

The effects and advantages of the present disclosure are not limited to the above-mentioned effects and advantages, and other effects that are not mentioned will be apparently understood by those skilled in the art from the following description and the appended claims.

### BRIEF DESCRIPTION OF THE DRAWINGS

The above and other objects, features, and advantages of the present disclosure will become more apparent to those of ordinary skill in the art by describing example embodiments thereof in detail with reference to the attached drawings, in which:

FIG. 1 is a block diagram illustrating a display device according to one embodiment of the present disclosure;

FIG. 2 is a cross-sectional view showing a cross-sectional structure of the display panel shown in FIG. 1;

FIGS. 3A and 3B are diagrams for explaining the structure of the pixel shown in FIG. 1;

FIG. 4 is a diagram illustrating a pixel circuit according to an embodiment of the present disclosure;

FIG. 5 is a diagram for explaining the principle of short-circuit generation between a cathode electrode and an anode electrode;

FIG. 6 is a cross-sectional view taken along line Al to A2 in FIG. 3B according to a first embodiment of the present disclosure;

FIG. 7 is a cross-sectional view of along line A1 to A2 in FIG. 3B according to a second embodiment of the present disclosure;

FIGS. 8A to 8D are diagrams for describing a repair process of a pixel circuit according to an embodiment of the present disclosure; and

FIG. 9 is a diagram for comparing and explaining whether a repair of a comparative example and an embodiment of the present disclosure is successful.

### DETAILED DESCRIPTION OF THE EMBODIMENTS

Advantages and features of the present specification and methods of achieving them will become apparent with reference to preferable embodiments, which are described in detail, in conjunction with the accompanying drawings. However, the present specification is not limited to the embodiments to be described below and can be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology can unnecessarily obscure the gist of the present disclosure, the detailed description thereof will be omitted.

When ‘including,’ ‘having,’ ‘consisting,’ and the like mentioned in the present specification are used, other parts can be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts can be located between the two parts unless ‘immediately’ or ‘directly’ is used.

Although first, second, and the like are used to describe various components, these components are not limited by these terms. These terms are only used to distinguish one component from another and may not define order or sequence. Accordingly, a first component, which is mentioned, below can also be a second component within the technical spirit of the present disclosure.

The same reference numerals can refer to substantially the same elements throughout the present disclosure. Further, the term “can” fully encompasses all the meanings and coverages of the term “may.”

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings. All the components of each circuit or device according to all embodiments of the present disclosure are operatively coupled and configured.

In a display device of the present disclosure, a pixel circuit and a gate driving circuit can include a plurality of transistors. Transistors can be implemented as oxide thin film transistors (oxide TFTs) including an oxide semiconductor, low temperature polysilicon (LTPS) TFTs including low temperature polysilicon, or the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons can flow from a source to a drain. The n-channel transistor has a direction of a current flowing from the drain to the source. In the case of a p-channel transistor (p-channel metal-oxide semiconductor (PMOS), since carriers are holes, a source voltage is higher than a drain voltage such that holes can flow from a source to a drain. In the p-channel transistor, since holes flow from the source to the drain, a current flows from the source to the drain. It should be noted that a source and a drain of a transistor are not fixed. For example, a source and a drain can be changed according to an applied voltage. Therefore, the disclosure is not limited due to a source and a drain of a transistor. In the following description, a source and a drain of a transistor will be referred to as a first electrode and a second electrode.

A gate signal swings between a gate-on voltage and a gate-off voltage. The gate-on voltage is set to a voltage higher than a threshold voltage of a transistor, and the gate-off voltage is set to a voltage lower than the threshold voltage of the transistor.

The transistor is turned on in response to the gate-on voltage and is turned off in response to the gate-off voltage. In the case of the n-channel transistor, a gate-on voltage can be a gate high voltage, and a gate-off voltage can be a gate low voltage. In the case of the p-channel transistor, a gate-on voltage can be a gate low voltage, and a gate-off voltage can be a gate high voltage.

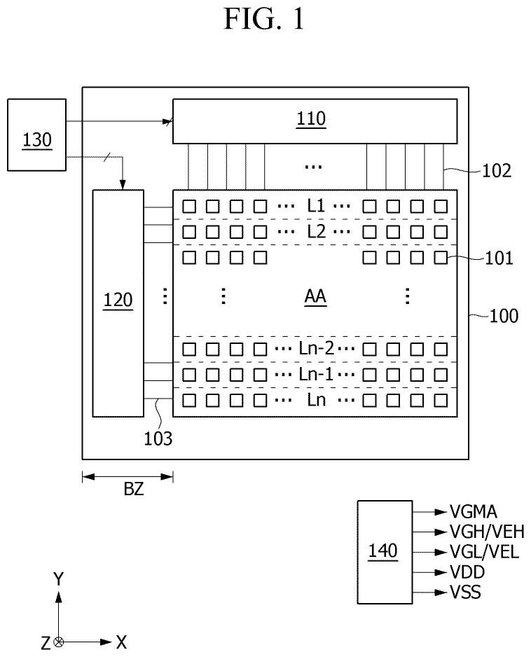

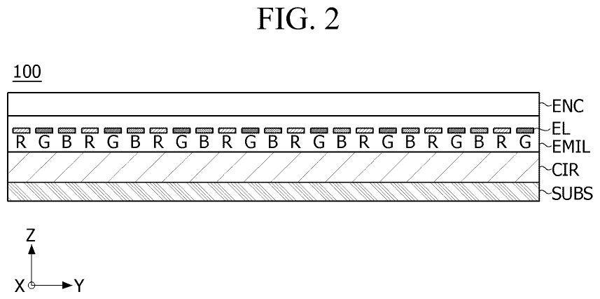

FIG. 1 is a block diagram illustrating a display device according to one embodiment of the present disclosure, and FIG. 2 is a cross-sectional view illustrating a cross-sectional structure of the display panel shown in FIG. 1.

Referring to FIGS. 1 and 2, the display device according to an embodiment of the present disclosure includes a display panel 100, a display panel driving unit configured to write pixel data to pixels of the display panel 100, and a power supply unit 140 configured to generate power used for driving the pixels and the display panel driving unit.

The display panel 100 includes a pixel array AA (or active area) that displays an input image. The pixel array AA includes a plurality of data lines 102, a plurality of gate lines 103 intersected with the data lines 102, and pixels arranged in a matrix form or other form.

The pixel array AA includes a plurality of pixel lines L1 to Ln where n is a real number. Each of the pixel lines L1 to Ln includes one line of pixels arranged along a line direction X in the pixel array AA of the display panel 100. Pixels arranged in one pixel line share the gate lines 103. Sub-pixels arranged in a column direction Y along a data line direction share the same data line 102. One horizontal period 1H is a time obtained by dividing one frame period by the total number of pixel lines L1 to Ln.

Touch sensors can be disposed on the display panel 100. A touch input can be sensed using separate touch sensors or can be sensed through pixels. The touch sensors can be disposed as an on-cell type or an add-on type on the screen of the display panel or implemented as in-cell type touch sensors embedded in the pixel array AA.

The display panel 100 can be implemented as a flexible display panel. The flexible display panel can be made of a plastic OLED panel. An organic thin film can be disposed on a back plate of the plastic OLED panel, and the pixel array AA can be formed on the organic thin film.

The back plate of the plastic OLED can be a polyethylene terephthalate (PET) substrate. The organic thin film is formed on the back plate. The pixel array AA and a touch sensor array can be formed on the organic thin film. The back plate blocks moisture permeation so that the pixel array AA is not exposed to humidity. The organic thin film can be a thin Polyimide (PI) film substrate. A multi-layered buffer film can be formed of an insulating material on the organic thin film. Lines can be formed on the organic thin film so as to supply power or signals applied to the pixel array AA and the touch sensor array.

To implement color, each of the pixels can be divided into a red sub-pixel (hereinafter referred to as “R sub-pixel”), a green sub-pixel (hereinafter referred to as “G sub-pixel”), and a blue sub-pixel (hereinafter referred to as “B sub-pixel”). Each of the pixels can further include a white sub-pixel. However, other color combinations of the sub-pixels are possible. Each of the sub-pixels 101 includes a pixel circuit. The pixel circuit is connected to the data line 102 and the gate line 103.

The cross-sectional structure of the display panel 100 can include a circuit layer CIR, a light-emitting element layer EMIL, and an encapsulation layer ENC stacked on a substrate SUBS, as shown in FIG. 2.

The circuit layer CIR can include a thin-film transistor (TFT) array including a pixel circuit connected to wirings such as a data line, a gate line, a power line, and the like, and a gate driver 410 and 420. The circuit layer CIR includes a plurality of metal layers insulated with insulating layers interposed therebetween, and a semiconductor material layer. All transistors formed in the circuit layer CIR can be implemented as n-channel oxide TFTs.

The light-emitting element layer EMIL can include a light-emitting element driven by the pixel circuit. The light-emitting element can include a light-emitting element of a red sub-pixel, a light-emitting element of a green sub-pixel, and a light-emitting element of a blue sub-pixel. The light-emitting element layer EMIL can further include a light-emitting element of white sub-pixel. The light-emitting element layer EMIL corresponding to each of the sub-pixels can have a structure in which a light-emitting element and a color filter are stacked. The light-emitting elements EL in the light-emitting element layer EMIL can be covered by multiple protective layers including an organic film and an inorganic film.

The encapsulation layer ENC covers the light-emitting element layer EMIL to seal the circuit layer CIR and the light-emitting element layer EMIL. The encapsulation layer ENC can also have a multi-insulating film structure in which an organic film and an inorganic film are alternately stacked. The inorganic film blocks permeation of moisture and oxygen. The organic film planarizes the surface of the inorganic film. When the organic layer and the inorganic layer are stacked in multiple layers, the movement path of moisture and oxygen becomes longer than that of a single layer, so that penetration of moisture and oxygen affecting the light-emitting element layer EMIL can be effectively blocked.

A touch sensor layer can be formed on the encapsulation layer ENC, and a polarizing plate or a color filter layer can be disposed thereon. The touch sensor layer can include capacitive touch sensors that sense a touch input based on a change in capacitance before and after the touch input. The touch sensor layer can have metal wiring patterns and insulating films that form the capacitance of the touch sensors. The insulating films can insulate an area where the metal wiring patterns intersect and can planarize the surface of the touch sensor layer. The polarizing plate can improve visibility and contrast ratio by converting the polarization of external light reflected by metal in the touch sensor layer and the circuit layer. The polarizing plate can be implemented as a circular polarizing plate or a polarizing plate in which a linear polarizing plate and a phase retardation film are bonded together. A cover glass can be adhered to the polarizing plate. The color filter layer can include red, green, and blue color filters. The color filter layer can further include a black matrix pattern. The color filter layer can replace the polarizing plate by absorbing a part of the wavelength of light reflected from the circuit layer and the touch sensor layer, and increase the color purity of an image reproduced in the pixel array.

The power supply unit 140 generates direct current (DC) power necessary to drive the display panel driving unit and the pixel array of the display panel 100 by using a DC-DC converter. The DC-DC converter can include a charge pump, a regulator, a buck converter, a boost converter, and the like. The power supply unit 140 can adjust a level of an input DC voltage applied from a host system to generate constant voltages (or DC voltages) such as a gamma reference voltage VGMA, gate-on voltages VGH and VEH, gate-off voltages VGL and VEL, the pixel driving voltage VDD, the low-potential power voltage VSS, the initialization voltage VINIT, and the reference voltage VREF. The gamma reference voltage VGMA is supplied to a data driver 110. The gate-on voltages VGH and VEH and the gate-off voltages VGL and VEL are supplied to a gate driver 120. The constant voltages such as the pixel driving voltage VDD, the low-potential power voltage VSS, the initialization voltage VINIT, and the reference voltage VREF are commonly supplied to the pixels.

The display panel driving unit writes pixel data of an input image to the pixels of the display panel 100 under control of a timing controller (TCON) 130.

The display panel driving unit includes the data drivers 110 and the gate drivers 130.

A de-multiplexer (DEMUX) can be disposed between the data driver 110 and the data lines 102. The de-multiplexer is omitted from FIG. 1. The de-multiplexer sequentially connects one channel of the data driver 110 to the plurality of data lines 102 and distributes in a time division manner the data voltage outputted from one channel of the data driver 110 to the data lines 102, thereby reducing the number of channels of the data driver 110.

The display panel driving circuit can further include a touch sensor driver for driving the touch sensors. In a mobile device, the timing controller 130, the power supply unit 140, the data driver 110, and the like can be integrated into one drive integrated circuit (IC).

The data driver 110 generates a data voltage Vdata by converting pixel data of an input image received from the timing controller 130 with a gamma compensation voltage every frame period by using a digital to analog converter (DAC). The gamma reference voltage VGMA is divided for respective gray scales through a voltage divider circuit. The gamma compensation voltage divided from the gamma reference voltage VGMA is provided to the DAC of the data driver 110. The data voltage Vdata is outputted through the output buffer in each of the channels of the data driver 110.

In the data driver 110, the output buffer included in one channel can be connected to adjacent data lines 102 through the de-multiplexer array 112. The de-multiplexer array 112 can be formed directly on the substrate of the display panel 100 or integrated into one drive IC together with the data driver 110.

The gate driver 120 can be implemented as a gate in panel (GIP) circuit formed directly on a bezel BZ area of the display panel 100 together with the TFT array of the pixel array AA. The gate driver 120 sequentially outputs gate signals to the gate lines 103 under the control of the timing controller 130. The gate driver 120 can sequentially supply the gate signals to the gate lines 103 by shifting the gate signals using a shift register.

The timing controller 130 receives, from a host system, digital video data DATA of an input image and a timing signal synchronized therewith. The timing signal includes a vertical synchronization signal Vsync, a horizontal synchronization signal Hsync, a main clock CLK, a data enable signal DE, and the like. Because a vertical period and a horizontal period can be known by counting the data enable signal DE, the vertical synchronization signal Vsync and the horizontal synchronization signal Hsync can be omitted. The data enable signal DE has a cycle of one horizontal period (1H).

The timing controller 130 multiplies an input frame frequency by i and controls the operation timing of the display panel driving circuit with a frame frequency of the input frame frequency×i (i is a positive integer greater than 0) Hz. The input frame frequency is 60 Hz in the NTSC (National Television Standards Committee) scheme and 50 Hz in the PAL (Phase-Alternating Line) scheme.

Based on the timing signals Vsync, Hsync, and DE received from the host system, the timing controller 130 generates a data timing control signal for controlling the operation timing of the data driver 110, MUX signals for controlling the operation timing of the de-multiplexer array 112, and a gate timing control signal for controlling the operation timing of the gate driver 120.

The voltage level of the gate timing control signal outputted from the timing controller 130 can be converted into the gate-on voltages VGH and VEH and the gate-off voltages VGL and VEL through a level shifter and then supplied to the gate driver 120. For example, the level shifter converts a low level voltage of the gate timing control signal into the gate-off voltages VGL and VEL and converts a high level voltage of the gate timing control signal into the gate-on voltages VGH and VEH. The gate timing signal includes the start pulse and the shift clock.

The host system can include a main board of one of a television system, a set-top box, a navigation system, a personal computer (PC), a home theater system, a vehicle system, and a mobile device system. In this case, the data driver 110, the gate driver 120, the timing controller 130, and the like can be integrated into one drive IC (DIC) in mobile devices or wearable devices.

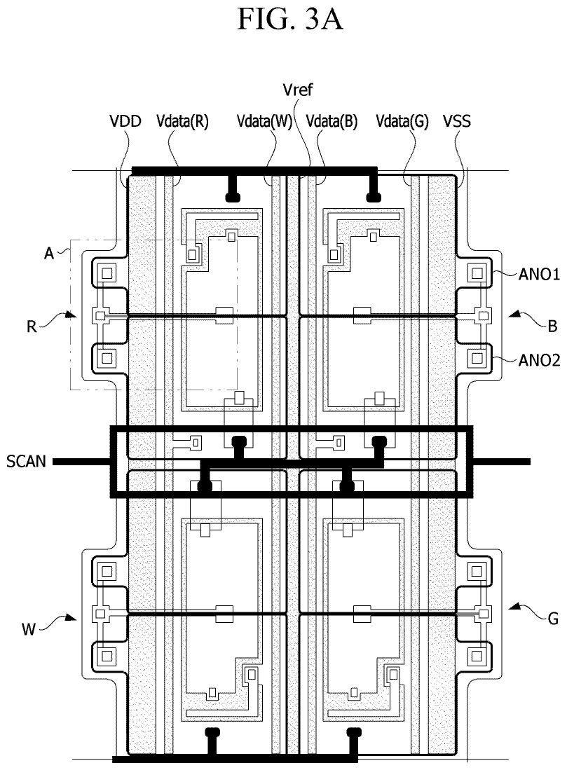

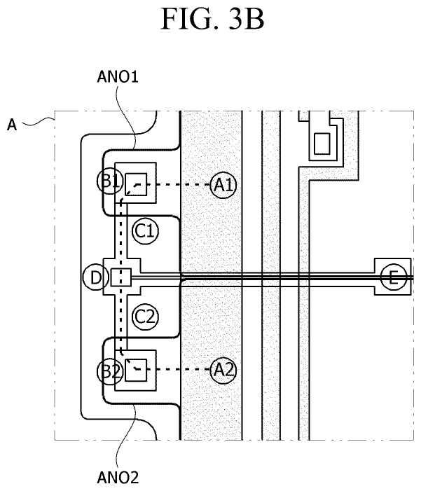

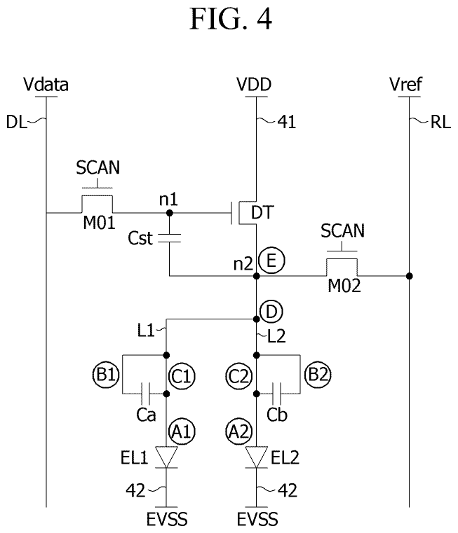

FIGS. 3A and 3B are diagrams for explaining the structure of the pixel shown in FIG. 1, and FIG. 4 is a diagram illustrating a pixel circuit according to an embodiment of the present disclosure. Particularly, FIG. 3B shows an enlarged view of area A of FIG. 3A. FIG. 4 shows an example of the pixel circuit including different areas/points from A1, B1, C1, D, C2, B2 and A2 in FIG. 3B.

Referring to FIGS. 3A and 3B, each of the pixels according to an embodiment of the present disclosure can include a plurality of sub-pixels. The plurality of sub-pixels can include red (R), green (B), blue (B), and white (W), but are not limited thereto.

Each of these pixels can include a pixel circuit that drives a light-emitting diode.

Referring to FIG. 4, the pixel circuit according to the embodiment includes a first light-emitting element EL1, a second light-emitting element EL2, a driving element DT that supplies a current to first and second light-emitting elements ELI and EL2, a plurality of switch elements M01 to M02 that switch a current path connected to the driving element DT, and a capacitor Cst that stores a gate-source voltage of the driving element DT. The driving element DT and the switch elements M01 to M02 can be implemented as an N-channel TFT, but are not limited thereto.

The first and second light-emitting elements EL emit light by a current applied through a channel of the driving element DT depending on the gate-source voltage Vgs of the driving element DT that changes depending on the data voltage Vdata. The first and second light-emitting elements EL can be implemented as an OLED including an organic compound layer formed between the anode and the cathode. The organic compound layer can include a hole injection layer (HIL), a hole transport layer (HTL), an emission layer (EML), an electron transport layer (ETL), an electron injection layer (EIL), and the like, but is not limited thereto. Anode electrodes of the first and second light-emitting elements EL1 and EL2 are connected to the driving element DT through a second node n2, and cathode electrodes of the first and second light-emitting elements EL1 and EL2 are connected to a low-potential power voltage line or a second power line 42 to which a low-potential power voltage VSS is applied.

The first and second light-emitting elements EL1 and EL2 are connected in parallel between the second node n2 and the second power line 42.

The driving element DT supplies a current to the light-emitting element EL depending on a gate-source voltage Vgs to drive the first and second light-emitting elements EL1 and EL2. The driving element DT includes a gate electrode connected to a first node n1, a first electrode (or a drain) connected to a pixel driving voltage line 41 to which a pixel driving voltage VDD is applied, and a second electrode (or a source) connected to the second node n2.

The first switch element M01 is turned on depending on a gate-on voltage of a gate signal SCAN to apply a data voltage Vdata to the first node n1 through a data line DL. The switch element M01 includes a gate electrode to which the gate signal SCAN is applied, a first electrode connected to the data line DL, and a second electrode connected to the first node n1.

A second switch element M02 is turned on depending on the gate-on voltage of the gate signal SCAN to apply a reference voltage Vref to the second node n2 through a reference voltage line RL. The second switch element M02 includes a gate electrode to which the gate signal SCAN is applied, a first electrode connected to the second node n2, and a second electrode connected to the reference voltage line RL.

The capacitor Cst can be connected between the first node n1 and the second node n2. The capacitor Cst can charge the gate-source voltage Vgs of the driving element DT.

The anode electrode connected to the second node n2 can be separately formed into a first anode electrode connected to the first light-emitting element EL1 and a second anode electrode connected to the second light-emitting element EL2.

One reason why the first anode electrode and the second anode electrode are separately formed is to use the light-emitting element of the remaining anode electrode without using the light-emitting element of the anode electrode in which the defect has occurred when a dark point defect has occurred due to the occurrence of a short circuit between the cathode electrode and the anode electrode.

A first repair capacitor Ca can be connected in parallel to the first connection line L1 connecting the second node n2 and the first anode electrode, and a second repair capacitor Cb can be connected in parallel to the second connection line L2 connecting the second node n2 and the second anode electrode. Here, the first repair capacitor Ca and the second repair capacitor Cb can be used for a secondary repair process in case of a primary repair failure for a dark point defect.

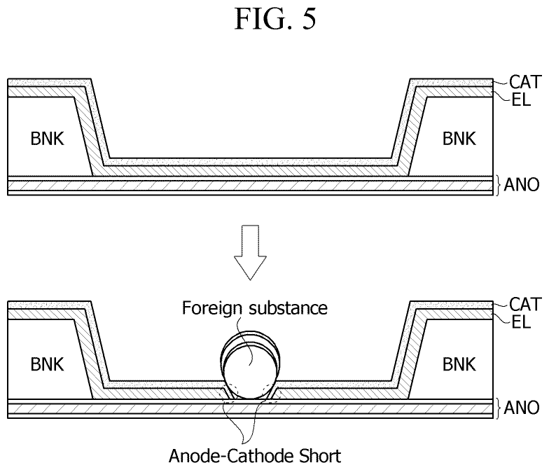

FIG. 5 is a diagram for explaining the principle of short-circuit generation between a cathode electrode and an anode electrode.

Referring to FIG. 5, when a foreign substance is introduced into the upper portion of the anode electrode in a top emission structure, the emission layer is stacked in a form that is disconnected from the periphery of the foreign substance, and the cathode electrode is stacked on the upper portion of the emission layer. The cathode electrode is deposited on the upper portion of the emission layer, but is also deposited between the emission layer and the foreign substance, so that the cathode electrode and the anode electrode contact each other to become an electrical short circuit state.

At this time, the cathode electrode is formed of a transparent metal material through which light passes in the top emission structure, and the transparent metal material sputters well even in a narrow space, so it is deposited between the emission layer and the foreign substance, which can cause a short circuit with the anode electrode.

Dark points can occur due to electrical short circuits between the cathode electrodes and the anode electrodes.

To solve this limitation, normal driving of the pixel can be possible by cutting an anode electrode in which an electrical short circuit occurs due to a foreign substance and using only the remaining anode electrodes.

In some cases, defects caused by foreign substances can be confirmed and repaired by the human eye, but in some cases, they may not be confirmed by the human eye. When it cannot be confirmed by the human eye, it is not known where the electrical short circuit occurred, so the anode electrode of any one of the two light-emitting elements is cut. However, when a normal anode electrode other than the anode electrode that has been defective by foreign substances is cut, additional repair may not be performed, so the pixel may not be driven normally, resulting in a decrease in the overall production yield.

Therefore, in an embodiment of the present disclosure, a wire is intended to be added to enable an additional repair. For example, in the embodiment, when a primary repair of cutting an anode electrode expected to be defective is performed, but fails, a secondary repair for connecting a wire added in advance to the cut anode electrode by welding and cutting other anode electrodes can be performed.

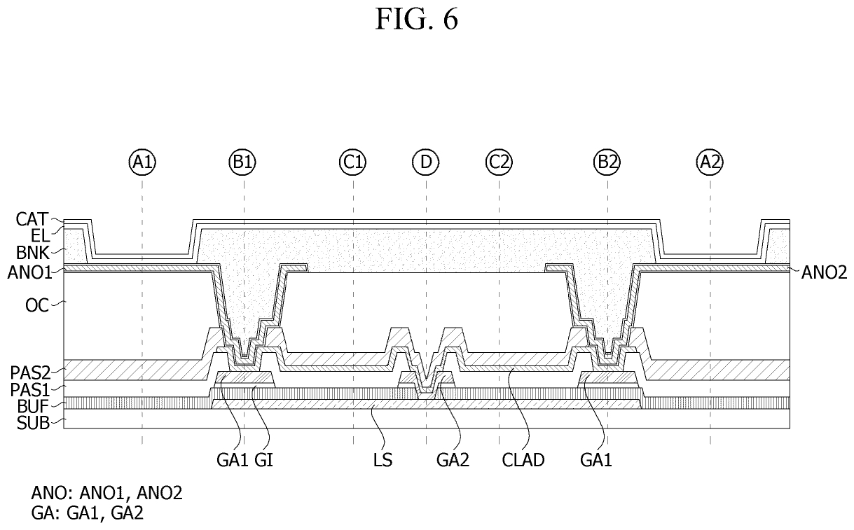

FIG. 6 is a cross-sectional view taken along line starting from A1 to A2 in FIG. 3B according to a first embodiment of the present disclosure.

Referring to FIG. 6, the display panel according to this embodiment can include a substrate SUB, a repair wire LS, a buffer layer BUF, a gate insulating film GI, a gate layer GA, a first passivation layer PAS1, a clad layer CLAD, a second passivation layer PAS2, an overcoat layer OC, an anode electrode ANO, an emission layer EL, and a cathode electrode CAT.

The substrate SUB can be made of plastic having flexibility. For example, the substrate SUB can be made of a single layer or multilayer substrate of a material selected from polyimide, polyethylene terephthalate, polyethylene naphthalate, polycarbonate, polyethersulfone, polyarylate, polysulfone, and cyclic olefin copolymer, but is not limited thereto. For example, the substrate SUB can be a ceramic substrate or a glass substrate.

A repair wire LS can be disposed on the substrate SUB, and a buffer layer BUF covering the repair wire LS can be disposed. The repair wire LS according to an embodiment can be electrically connected to the anode electrode ANO by laser light when the clad layer CLAD is cut, and a source node of the driving element can be connected to the anode electrode ANO instead of the cut clad layer CLAD. The central portion of the repair wire LS can be connected to the central portion of the clad layer to which the source node of the driving element is connected.

The buffer layer BUF serves to protect the thin film transistor formed in the subsequent process from impurities such as alkali ions flowing out of the substrate SUB. The buffer layer BUF can be silicon oxide (SiOx), silicon nitride (SiNx), or a multilayer thereof.

On the buffer layer BUF, a gate insulating film GI and a gate layer GA can be stacked, and a first passivation layer PASI covering the gate insulating film GI and the gate layer GA can be disposed. The gate insulating film GI can be silicon oxide (SiOx), silicon nitride (SiNx), or a multilayer thereof.

At the point D connected to the source node of the driving element, the buffer layer BUF and the gate insulating film GI can expose a part of the repair wire LS so that the gate layer GA is electrically connected to the repair wire LS.

One surface of the gate layer GA according to an embodiment of the present disclosure can be electrically connected to the clad layer CLAD, and the other surface thereof can be electrically connected to the repair wire LS. The gate layer GA can be formed of any one or an alloy thereof selected from the group consisting of molybdenum (Mo), aluminum (Al), chromium (Cr), gold (Au), titanium (Ti), nickel (Ni), neodymium (Nd), and copper (Cu). Furthermore, the gate layer GA can be a multilayer composed of any one or an alloy thereof selected from the group consisting of molybdenum (Mo), aluminum (Al), chromium (Cr), gold (Au), titanium (Ti), nickel (Ni), neodymium (Nd), and copper (Cu). For example, the gate layer GA can be a double layer of molybdenum/aluminum-neodymium or molybdenum/aluminum.

In this case, the gate layer GA can include a first gate layer GA1 and a second gate layer GA2. The first gate layer GA1 can be electrically connected to the first anode electrode ANO1 and the second anode electrode ANO2. The second gate layer GA2 can be formed separately so as not to be electrically connected to the first gate layer GA1. The second gate layer GA2 can be disposed at the point D connected to the source electrode of the driving element to electrically connect the clad layer CLAD and the repair wire LS to each other.

A clad layer CLAD can be disposed on the first passivation layer PAS1, and a second passivation layer PAS2 covering the clad layer CLAD can be disposed. The second passivation layer PAS2 can have a contact hole formed to expose a part of the clad layer CLAD so that the anode electrode and the clad layer CLAD are electrically connected.

An overcoat layer OC can be disposed on the second passivation layer PAS2. The overcoat layer OC can be a planarization film for mitigating the step difference of the lower structure, and can be made of an organic material such as polyimide, benzocyclobutene series resin, acrylate, and the like. The overcoat layer OC can expose a portion of the second passivation layer PAS2 so that the anode electrode and the clad layer are electrically connected.

An anode electrode ANO can be disposed on the overcoat layer OC. The anode electrode ANO can penetrate the overcoat layer OC and the second passivation layer PAS2 to be electrically connected to the clad layer CLAD. The anode electrode ANO can include a first anode electrode ANO1 of the first light-emitting element and a second anode electrode ANO2 of the second light-emitting element. The first anode electrode ANO1 can be electrically connected to one surface of the clad layer CLAD, and the second anode electrode ANO2 can be electrically connected to the other surface of the clad layer CLAD. In this case, the anode electrode ANO can have a stacked structure of an indium tin oxide (ITO) and a molybdenum-titanium alloy (MoTi). For example, the anode electrode ANO can be formed of a first layer of ITO, a second layer of MoTi, and a third layer of ITO, but is not limited thereto.

A bank layer BNK covering a portion of the anode electrode ANO can be disposed on the anode electrode ANO. The bank layer BNK can expose a portion of the anode electrode ANO so that the anode electrode ANO and the emission layer EL are electrically connected.

An emission layer EL can be disposed on the bank layer BNK. The emission layer EL can penetrate the bank layer BNK to be electrically connected to the anode electrode ANO.

A cathode electrode CAT can be disposed on the emission layer EL. The cathode electrode CAT can be a thin metal electrode through which light is transmitted. The cathode electrode CAT can be, for example, a transparent conductive material such as an indium tin oxide (ITO) or an indium zinc oxide (IZO), or a metal through which visible light is transmitted, but is not limited thereto.

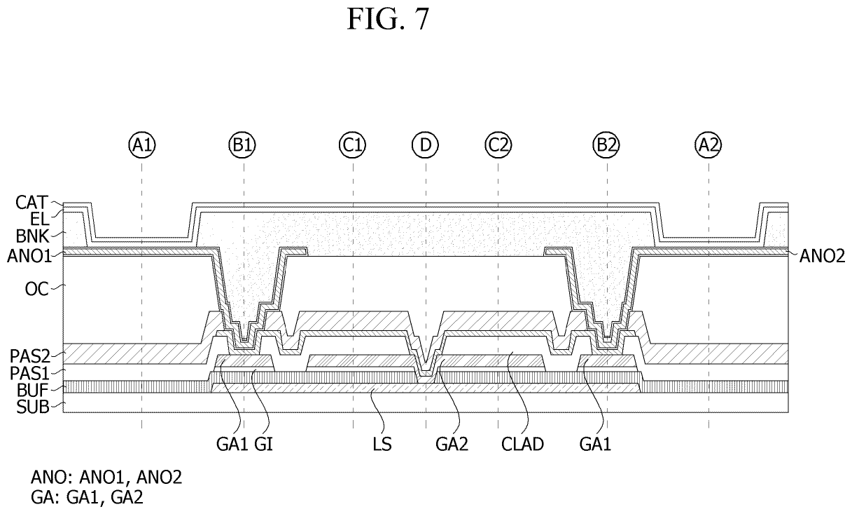

FIG. 7 is a cross-sectional view taken along line A1 to A2 in FIG. 3B according to a second embodiment of the present disclosure.

Referring to FIG. 7, the display panel according to this embodiment can include a substrate SUB, a repair wire LS, a buffer layer BUF, a gate insulating film GI, a gate layer GA, a first passivation layer PAS1, a clad layer CLAD, a second passivation layer PAS2, an overcoat layer OC, an anode electrode ANO, an emission layer EL, and a cathode electrode CAT.

The substrate SUB can be made of plastic having flexibility.

A repair wire LS can be disposed on the substrate SUB, and a buffer layer BUF covering the repair wire LS can be disposed. When the clad layer CLAD is cut, the repair wire LS according to an embodiment of the present disclosure can be electrically connected to the anode electrode ANO by laser light, and a driving current flowing through the driving element can be transmitted to the anode electrode ANO instead of the cut clad layer CLAD.

A gate insulating film GI and a gate layer GA can be stacked on the buffer layer BUF, and a first passivation layer PASI covering the gate insulating film GI and the gate layer GA can be disposed. The gate insulating film GI can be silicon oxide (SiOx), silicon nitride (SiNx), or a multlayer thereof.

At the point D connected to the source node of the driving element, the buffer layer BUF and the gate insulating film GI can expose a portion of the repair wire LS so that the gate layer GA is electrically connected to the repair wire LS.

In this case, the gate layer GA can include a first gate layer GA1 and a second gate layer GA2. The first gate layer GA1 can be electrically connected to the first anode electrode ANO1 and the second anode electrode ANO2. The second gate layer GA2 can be formed separately so as not to be electrically connected to the first gate layer GA1. The second gate layer GA2 can be disposed at a point D connected to a source node of the driving element to electrically connect the clad layer CLAD and the repair wire LS to each other. The second gate layer GA2 disposed on the gate insulating film GI can be disposed side by side with the clad layer CLAD, and can block an influence of the laser light cutting the clad layer CLAD on a lower portion thereof.

A clad layer CLAD can be disposed on the first passivation layer PAS1, and a second passivation layer PAS2 covering the clad layer CLAD can be disposed. The second passivation layer PAS2 can expose a portion of the clad layer CLAD so that the anode electrode and the clad layer CLAD are electrically connected.

An overcoat layer OC can be disposed on the second passivation layer PAS2. The overcoat layer OC can expose a portion of the second passivation layer PAS2 so that the anode electrode and the clad layer are electrically connected.

An anode electrode ANO can be disposed on the overcoat layer OC. The anode electrode ANO can penetrate the overcoat layer OC and the second passivation layer PAS2 to be electrically connected to the clad layer CLAD. The anode electrode ANO can include a first anode electrode ANO1 of the first light-emitting element and a second anode electrode ANO2 of the second light-emitting element. The first anode electrode ANO1 can be electrically connected to one surface of the clad layer CLAD, and the second anode electrode ANO2 can be electrically connected to the other surface of the clad layer CLAD.

A bank layer BNK covering a portion of the anode electrode ANO can be disposed on the anode electrode ANO. The bank layer BNK can expose a portion of the anode electrode ANO so that the anode electrode ANO and the emission layer EL are electrically connected.

An emission layer EL can be disposed on the bank layer BNK. The emission layer EL can penetrate the bank layer BNK to be electrically connected to the anode electrode ANO.

A cathode electrode CAT can be disposed on the emission layer EL. The cathode electrode CAT can be a thin metal electrode through which light is transmitted. The cathode electrode CAT can be, for example, a transparent conductive material such as an indium tin oxide (ITO) or an indium zinc oxide (IZO), or a metal through which visible light is transmitted, but is not limited thereto.

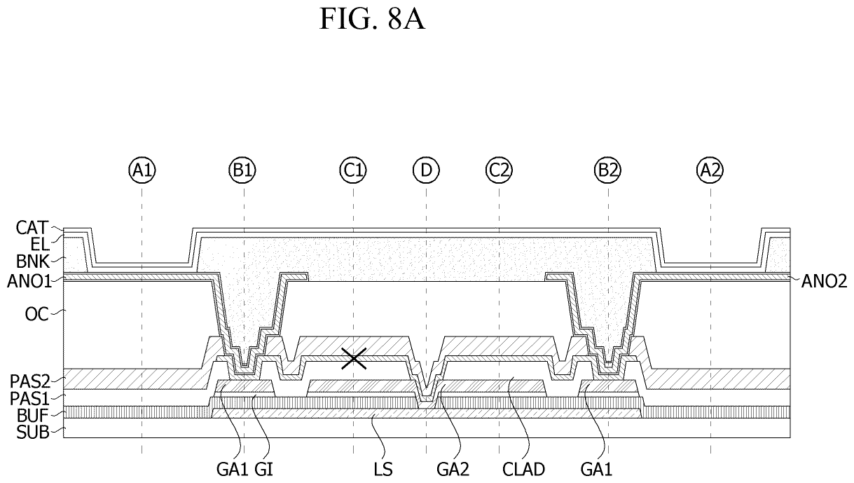

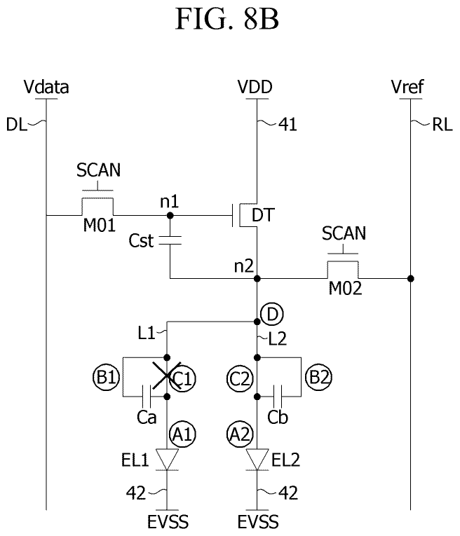

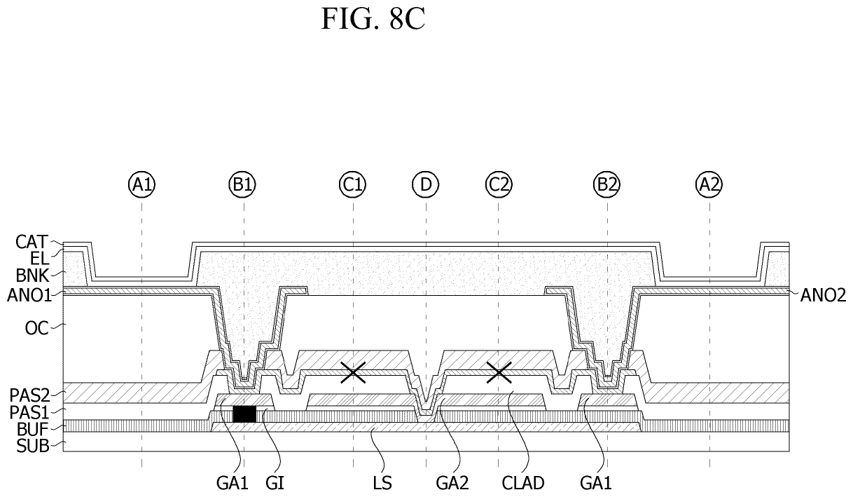

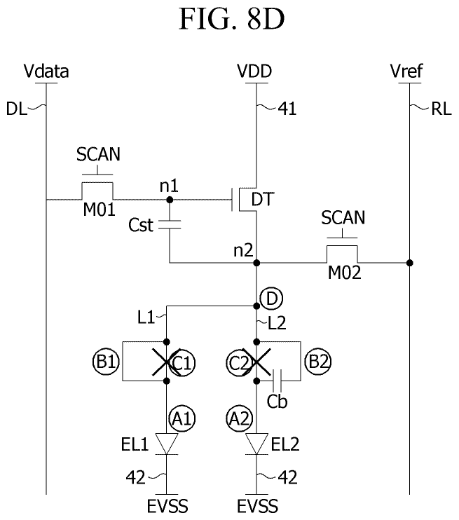

FIGS. 8A to 8D are diagrams for describing a repair process of a pixel circuit according to an embodiment of the present disclosure.

Referring to FIG. 8A, when a short circuit occurs between the anode electrode and the cathode electrode of either the first light-emitting element and the second light-emitting element, but cannot be confirmed with the naked eye, the clad layer applying a voltage to the anode electrode of the first light-emitting element can be cut using laser light to perform a primary repair process.

As a result of performing the primary repair process, the wire connected to the anode electrode of the first light-emitting element EL1 of the pixel is cut as shown in FIG. 8B, and the second light-emitting element EL2 can emit light normally.

On the other hand, when the second light-emitting element is turned into a dark point as a result of performing the primary repair process, it can be confirmed that a short circuit occurs between the anode electrode and the cathode electrode of the second light-emitting element, not the anode electrode of the first light-emitting element.

Referring to FIG. 8C, a secondary repair process can be performed to weld the repair wire connected to the clad layer and the anode electrode of the first light-emitting element using laser light so that driving current is applied to the anode electrode of the first light-emitting element through the clad layer, the gate layer, and the repair wire.

Additionally, the clad layer that applies a voltage to the anode electrode of the second light-emitting element, which is confirmed to have a short circuit as a result of performing the primary repair, can be cut using laser light to block the voltage from being applied to the anode electrode of the second light-emitting element.

As a result of performing the secondary repair process, the wire connected to the anode electrode of the first light-emitting element EL1 of the pixel is connected again as shown in FIG. 8D, and the wire connected to the anode electrode of the second light-emitting element EL2 is cut, so that the first light-emitting element EL1 can emit light normally.

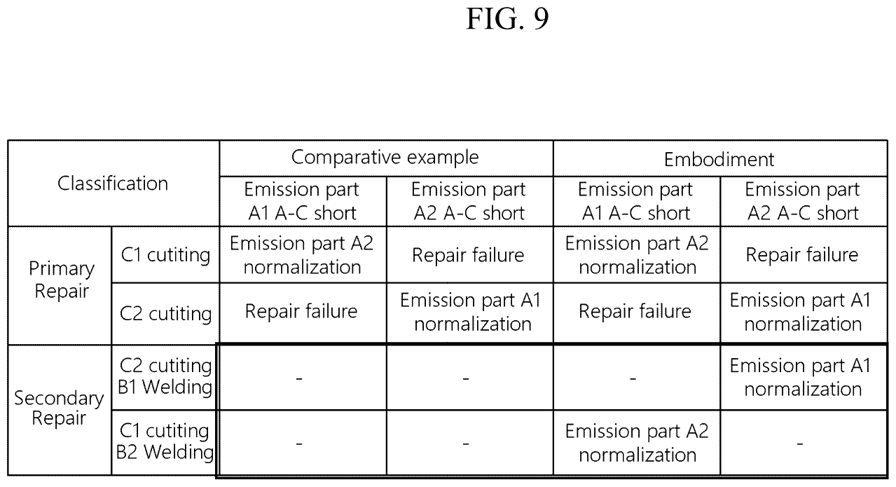

FIG. 9 is a diagram for comparing and explaining whether a repair of a comparative example and an embodiment of the present disclosure is successful.

Referring to FIG. 9, a repair process between a comparative example without additional wire and an embodiment of the present disclosure with additional wire is shown. In the comparative example, after performing the primary repair process, a clad layer connected to the anode electrode of the light-emitting element considered to have a foreign substance defect is cut, so that the light-emitting element can normally emit light.

However, it is impossible to perform an additional repair process when the anode electrode of the light-emitting element, which is considered to have a foreign substance defect, is not properly selected.

For example, in the comparative example, even if the primary repair process fails, an additional repair process is not possible. Therefore, when the location of the foreign substance is not confirmed, the repair success probability becomes 50%.

On the other hand, in the embodiment of the present disclosure, after performing the primary repair process, the clad layer connected to the anode electrode of the light-emitting element, which is considered to have a foreign substance defect, can be cut to normally emit light.

When the anode electrode of the light-emitting element that is considered to have a foreign substance defect is not properly selected, a secondary repair process can be performed to normally emit light of the light-emitting element.

For example, when the primary repair process is performed to cut the clad layer connected to the anode electrode of the first light-emitting element, but the primary repair fails, a secondary repair process can be performed in which the repair wire is connected to the anode electrode of the first light-emitting element through welding and the clad layer connected to the anode electrode of the second light-emitting element is cut.

As another example, when the primary repair process is performed to cut the clad layer connected to the anode electrode of the second light-emitting element, but the primary repair fails, a secondary repair process can be performed in which the repair wire is connected to the anode electrode of the second light-emitting element through welding and the clad layer connected to the anode electrode of the first light-emitting element is cut.

As described above, in the embodiment of the present disclosure, even if the repair fails, an additional repair can be performed. Therefore, even when the location of the foreign substance is not confirmed, the probability of a repair success becomes 100%.

Although the embodiments of the present disclosure have been described in more detail with reference to the accompanying drawings, the present disclosure is not limited thereto and can be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A pixel circuit comprising:
a first light-emitting element;
a second light-emitting element;
a driving element configured to drive the first and second light-emitting elements;
a first connection line connected between a source node of the driving element and a first anode electrode of the first light-emitting element;
a second connection line connected between the source node of the driving element and a second anode electrode of the second light-emitting element;
a first repair capacitor connected in parallel to the first connection line; and
a second repair capacitor connected in parallel to the second connection line.

2. The pixel circuit of claim 1, wherein the first and second connection lines are cut by laser light depending on a position of a foreign substance.

3. The pixel circuit of claim 1, wherein two electrodes of the first and second repair capacitors are short-circuited depending on a position of a foreign substance.

4. A display device comprising:
a substrate;
a repair wire disposed on the substrate;
a buffer layer covering the substrate on which the repair wire is disposed;
a first passivation layer disposed on the buffer layer and exposing a portion of the buffer layer;
a clad layer disposed on the first passivation layer;
a second passivation layer disposed on the clad layer and exposing a portion of the clad layer;
an overcoat layer disposed on the second passivation layer and exposing a portion of the clad layer;
a first anode electrode disposed on one side of the overcoat layer and electrically connected to one side of the clad layer through the overcoat layer and the second passivation layer; and
a second anode electrode disposed on another side of the overcoat layer and electrically connected to another side of the clad layer through the overcoat layer and the second passivation layer.

5. The display device of claim 4, wherein the clad layer includes:
a central portion to which a source node of a driving element is connected and which is connected to the repair wire,
a first end connected to the first anode electrode, and
a second end connected to the second anode electrode.

6. The display device of claim 5, wherein the clad layer is cut by laser light between the central portion and the first end of the clad layer, or between the central portion and the second end of the clad layer, depending on a position of an introduced foreign substance.

7. The display device of claim 6, wherein the clad layer is welded between the first end thereof and one end of the repair wire or between the second end thereof and another end of the repair wire, depending on the position of the introduced foreign substance.

8. The display device of claim 4, further comprising:
a gate insulating film and a gate layer stacked on the buffer layer,
wherein the first passivation layer covers the buffer layer on which the gate insulating film and the gate layer are stacked.

9. The display device of claim 8, wherein:
the first end of the clad layer is electrically connected to one end of the gate layer, and
the second end of the clad layer is electrically connected to another end of the gate layer.

10. The display device of claim 9, wherein the gate layer is welded between the first end and one end of the repair wire or between the second end and another end of the repair wire, depending on a position of an introduced foreign substance.
